(19) United States
(12) Patent Application Publication
(10) Pub. No.: US 2009/0102779 A1
(43) Pub. Date: Apr. 23, 2009

(54) Gate-off volatage generating circuit, driving device and liquid crystal dispaly including the same

(76) Inventor: Jo-Yeon Jo, Asan-si (KR)

Correspondence Address: MACPHERSON KWOK CHEN & HEID LLP, 2033 GATEWAY PLACE, SUITE 400, SAN JOSE, CA, 95110, US

(21) Appl. No.: 12/220,109

(22) Filed: Jul. 22, 2008

(30) Foreign Application Priority Data
Oct. 17, 2007 (KR) 10-2007-0104619

(51) Int. Cl. H03K 17/14; G09G 3/36

(52) U.S. Cl. 345/101; 327/378; 345/204

(57) ABSTRACT

A gate-off-voltage-generating circuit that can enhance display quality at low temperatures, a driving device, and a liquid crystal display having the same are provided. The driving device includes a boost converter to receive and boost a first input voltage, and output a driving voltage and a pulse signal; a gate-on voltage generator to receive the driving voltage and output a gate-on voltage; and a gate-off voltage generator including a first temperature-compensation unit to receive the driving voltage and output a first temperature-dependent variable voltage, the level of which varies according to the ambient temperature, a first voltage follower to receive and transfer the first temperature-dependent variable voltage, and a first charge-pumping unit to shift the first temperature-dependent variable voltage by the amplitude of the pulse signal and output a gate-off voltage.

### CROSS-REFERENCE TO RELATED APPLICATION

This application claims priority from Korean Patent Application No. 10-2007-0104619 filed on Oct. 17, 2007 in the Korean Intellectual Property Office, the disclosure of which is incorporated herein by reference in its entirety.

### BACKGROUND OF THE INVENTION

1. Technical Field

The present disclosure relates to a gate-off voltage generating circuit, a driving device having the gate-off voltage generating circuit, and a liquid crystal display having the same.

2. Discussion of the Related Art

Generally, liquid crystal displays include a liquid crystal panel having a plurality of gate lines and a plurality of data lines, a gate driver providing gate-driving signals to the plurality of gate lines, and a data driver providing data signals to the plurality of data lines. To achieve miniaturization and increased manufacturability, a structure has recently been developed in which a gate driver having a plurality of thin film transistors is formed on a predetermined area of a liquid crystal panel.

A gate driver formed on a liquid crystal panel includes at least one shift register having a plurality of thin film transistors (TFTs). The driving capacity of the TFTs varies depending upon the ambient temperature. That is, if the ambient temperature is lowered, the current driving capacity of the TFTs of a gate driver is reduced, such that the voltage level of the output gate-on voltage and/or the output gate-off voltage is not sufficient to drive the TFTs in a pixel array. As a result, the display quality of the liquid crystal display may deteriorate as the ambient temperature decreases.

### SUMMARY OF THE INVENTION

There is a need to provide a gate-off voltage generating circuit that can control the gate-off voltage according to the ambient temperature to enhance the display quality, a driving device, and a display apparatus having the same.

Exemplary embodiments of the present invention provide a gate-off-voltage-generating circuit that can enhance a display quality.

Exemplary embodiments of the present invention provide a driving device that can enhance a display quality.

Exemplary embodiments of the present invention provide a liquid crystal display having a driving device that can enhance a display quality.

These and other aspects of the present invention will be described in or be apparent from the following description of the exemplary embodiments.

According to an exemplary embodiment of the present invention, there is provided a gate-off voltage generating circuit including a voltage follower to receive and transfer a temperature-dependent variable voltage; and a charge-pumping unit to shift the transferred temperature-dependent variable voltage by the amplitude of a pulse signal and output a gate-off voltage.

According to an exemplary embodiment of the present invention, there is provided a driving device including a boost converter to receive and boost a first input voltage and output a driving voltage and a pulse signal; a gate-on voltage generator to receive the driving voltage and output a gate-on voltage; and a gate-off voltage generator including a first temperature-compensation unit to receive the driving voltage and output a first temperature-dependent variable voltage, the level of which varies according to the ambient temperature, a first voltage follower to receive and transfer the first temperature-dependent variable voltage, and a first charge-pumping unit to shift the first temperature-dependent variable voltage by the amplitude of the pulse signal and output a gate-off voltage.

According to an exemplary embodiment of the present invention, there is provided a liquid crystal display including: a driving device including a boost converter to receive and boost a first input voltage and output a driving voltage and a pulse signal, a gate-on voltage generator to receive the driving voltage and output a gate-on voltage, a gate-off voltage generator including a first temperature-compensation unit to receive the driving voltage and output a first temperature-dependent variable voltage, the level of which varies according to the ambient temperature, a first voltage follower to receive and transfer the first temperature-dependent variable voltage, and a first charge-pumping unit to shift the transferred first temperature-dependent variable voltage by the amplitude of the pulse signal and output a gate-off voltage, and a clock generator unit generating a clock signal having a swing of a voltage difference between the gate-on voltage and the gate-off voltage; a gate driver to receive the clock signal and output a gate signal; and a liquid crystal panel that includes a plurality of pixels to be turned on/off according to the gate signal and that displays an image.

### BRIEF DESCRIPTION OF THE DRAWINGS

Exemplary embodiments of the present invention will be understood in more detail from the following descriptions taken in conjunction with the attached drawings, in which:

FIG. 1 is a block diagram of a liquid crystal display according to an exemplary embodiment of the present invention;

FIG. 2 is an equivalent circuit diagram of a pixel in a liquid crystal display according to an exemplary embodiment of the present invention;

FIG. 3 is a block diagram of the gate-voltage generator shown in FIG. 1;

FIG. 4 is a circuit diagram of the boost converter shown in FIG. 3;

FIGS. 5A and 5B are circuit diagrams illustrating respectively first embodiments for the first and second temperature-compensation units shown in FIG. 3 according to an exemplary embodiment of the present invention;

FIG. 6 is a circuit diagram illustrating the first and second charge-pumping units shown in FIG. 3;

FIG. 7 is a circuit diagram illustrating the voltage follower shown in FIG. 3;

FIG. 8 is a diagram illustrating a voltage margin at room temperature and at a low temperature;

FIG. 9 is an exemplary block diagram illustrating a gate driver;

FIG. 10 is an exemplary circuit diagram of the j-th stage shown in FIG. 9;

FIG. 11 is a signal diagram illustrating a clock signal and a clock bar signal input to the gate driver and a gate signal output from the gate driver;

FIGS. 12A and 12B are circuit diagrams illustrating respectively alternative embodimats for the first and second temperature-compensation units shown in FIG. 3 according to an exemplary embodiment of the present invention;

FIG. 13 is a block diagram illustrating a gate-voltage generator according to a first alternative exemplary embodiment of the present invention; and

FIG. 14 is a block diagram illustrating a gate-voltage generator according to a second alternative exemplary embodiment of the present invention.

### DETAILED DESCRIPTION OF EXEMPLARY EMBODIMENTS

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. Like numbers refer to like elements throughout. As used herein, the term “and/or” includes any and all combinations of one or more of the associated listed items.

It should be understood that, although the terms first, second, and others may be used herein to describe various elements, components, and/or sections, these elements, components, and/or sections should not be limited by these terms. These terms are only used to distinguish one element, component, or section from another element, component, or section. Thus, a first element, component, or section discussed below could be termed a second element, component, or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and “comprising,” when used in this specification, specify the presence of stated features, integers, steps, operations, elements, and/or components, but do not preclude the presence or addition of one or more other features, integers, steps, operations, elements, components, and/or groups thereof.

Unless explicitly stated otherwise, all of the terminologies (including technical and scientific terminologies) used herein may be used as meaning that those skilled in the art can commonly understand. Further, terminologies defined in ordinary dictionaries should not be ideally or excessively construed, unless explicitly stated otherwise.

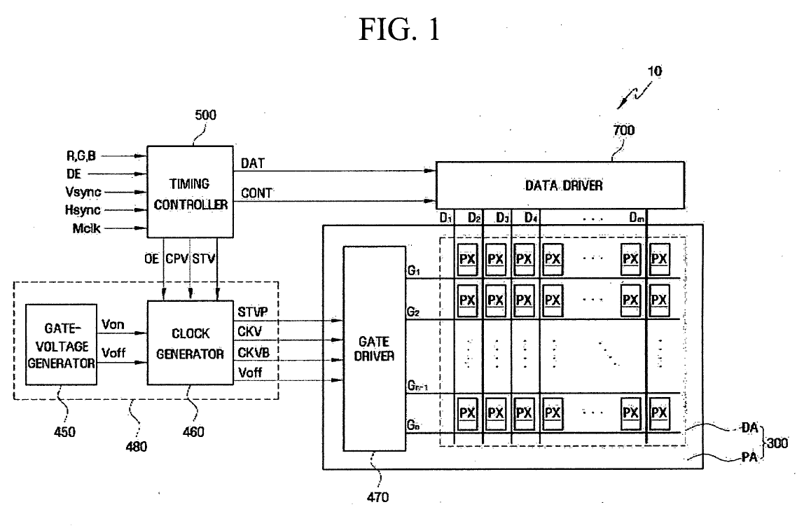

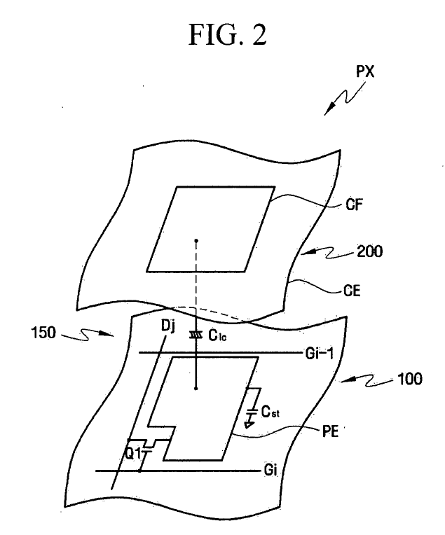

FIG. 1 is a block diagram of a liquid crystal display (10) according to an exemplary embodiment of the present invention and FIG. 2 is an equivalent circuit diagram of a pixel in a liquid crystal display according to an exemplary embodiment of the present invention.

Referring to FIG. 1, the liquid crystal display 10 according to an exemplary embodiment of the present invention includes a liquid crystal panel 300, a gate-voltage generator 450, a timing controller 500, a clock generator 460, a gate driver 470 and a data driver 700. A driving device 480 includes the gate-voltage generator 450 and the clock generator 460.

The liquid crystal panel 300 is divided into a display area DA, where an image is displayed, and a non-display area PA, where an image is not displayed.

The display area DA includes a first substrate 100, which includes a plurality of gate lines G1 to Gn, a plurality of data lines D1 to Dm, switching elements Q1 and pixel electrodes PE formed thereon, a second substrate 200, which includes color filters CF and a common electrode CE formed thereon and a liquid crystal layer 150 interposed between the first substrate 100 and the second substrate 200, such that an image is displayed within the display area DA. The gate lines G1 to Gn extend in a first direction, such as a row direction, so as to be substantially parallel with one another, and the data lines D1 to Dm extend in a second direction, such as a column direction, so as to be substantially parallel with one another. In exemplary embodiments, the first direction is substantially perpendicular to the second direction.

Referring to FIGS. 1 and 2, in exemplary embodiments, a pixel PX includes a color filter CF which may be formed on an area of the common electrode CE of the second substrate 200, such that the color filter CF is disposed to face the pixel electrode PE of the first substrate 100. In an exemplary embodiment, the pixel PX further includes the switching element Q1 which is connected to the pixel electrode PE and to an i-th gate line Gi (i=1 to n) and to a j-th data line Dj (j=1 to m). The liquid crystal capacitor Clc and a storage capacitor Cst are connected to the switching element Q1. However, in exemplary embodiments, the storage capacitor Cst may be omitted. In further exemplary embodiments, the switching element Q1 may be a thin film transistor (“a-Si TFT”) made from amorphous silicon.

The first substrate 100 (see FIG. 2) is larger in size than the second substrate 200 (see FIG. 2), and includes the non-display area PA which does not display an image. The gate driver 470 of FIG. 1 may be mounted on the non-display area PA or may be formed with TFTs on the non-display area PA.

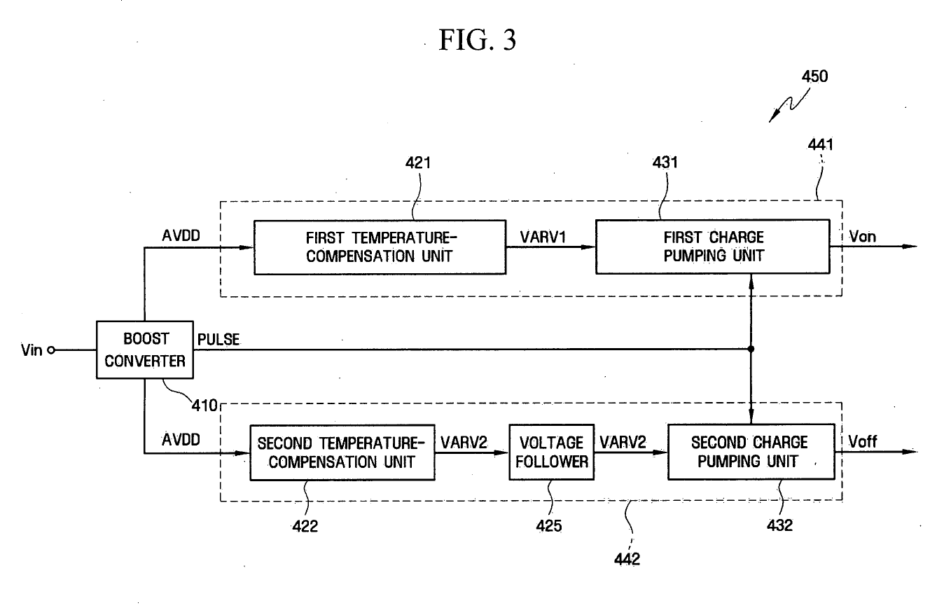

The gate-voltage generator 450 generates a gate-on voltage Von and a gate-off voltage Voff, and supplies the gate-on voltage Von and the gate-off voltage Voff to a clock generator 460. Here, the voltage level of the gate-on voltage Von and/or the gate-off voltage Voff may vary according to the ambient temperature. For example, the voltage level of the gate-on voltage Von increases when the ambient temperature falls, and the voltage level of the gate-on voltage Von decreases when the ambient temperature rises. The voltage level of the gate-off voltage Voff decreases when the ambient temperature falls and the voltage level of the gate-off voltage Voff increases when the ambient temperature rises. The gate-voltage generator 450 will be described later in more detail with reference to FIGS. 3 to 8.

The timing controller 500 is supplied by an external graphic controller (not shown) with input image signals R, G and B and input control signals controlling the display of the input image signals R, G and B, the input control signals including a horizontal synchronization signal Hsync, a main clock Mclk, a data enable signal DE, and other signals, and outputs the data control signal CONT and the image data signal DAT to the data driver 700. Here, the data control signal CONT includes a horizontal synchronization start signal for starting the operation of the data driver 700, a load signal for instructing outputs of two data voltage signals, and so on.

Also, the timing controller 500 outputs a first clock-generation-control signal OE, a second clock-generation-control signal CPV and an original scan-start signal STV to the clock generator 460. Here, the first clock-generation-control signal OE may be a gate enable signal which enables the gate signal, the second clock generation control signal CPV is a gate clock signal which determines a duty ratio of the gate signal, and the original scan start signal STV is a signal which indicates and/or initiates the start of one frame.

The clock generator 460 receives the first clock-generation-control signal OE, the second clock-generation-control signal CPV and the original scan-start signal STV from the timing controller 500, receives the gate-on voltage Von and the gate-off voltage Voff from the gate-voltage generator, and outputs a clock signal CKV, a clock bar signal CKVB and the gate-off voltage Voff, using the gate-on voltage Von and the gate-off voltage Voff outputted from the gate-voltage generator 450. Here, the clock signal CKV and the clock bar signal CKVB may have a swing of a predetermined voltage difference between the gate-on voltage Von and the gate-off voltage Voff. The clock signal CKV may have a phase different from that of the clock bar signal CKVB.

Also, the clock generator 460 converts the original scan-start signal STV to a scan-start signal STVP and outputs the scan-start signal STVP to the gate driver 470. The clock generator 460 amplifies the amplitude of the original scan-start signal STV and generates the scan-start signal STVP.

When the ambient temperature decreases, the clock generator 460 outputs a clock signal CKV having an increased amplitude and a clock bar signal CKVB corresponding thereto of a different phase. In contrast, when the ambient temperature increases, the clock generator 460 outputs a clock signal CKV having a decreased amplitude and a clock bar signal CKVB corresponding thereto having a different phase. The amplitudes of the clock signal CKV and the clock bar signal CKVB are adjusted according to a variation of the voltage levels of Von and/or Voff depending on a change in the ambient temperature.

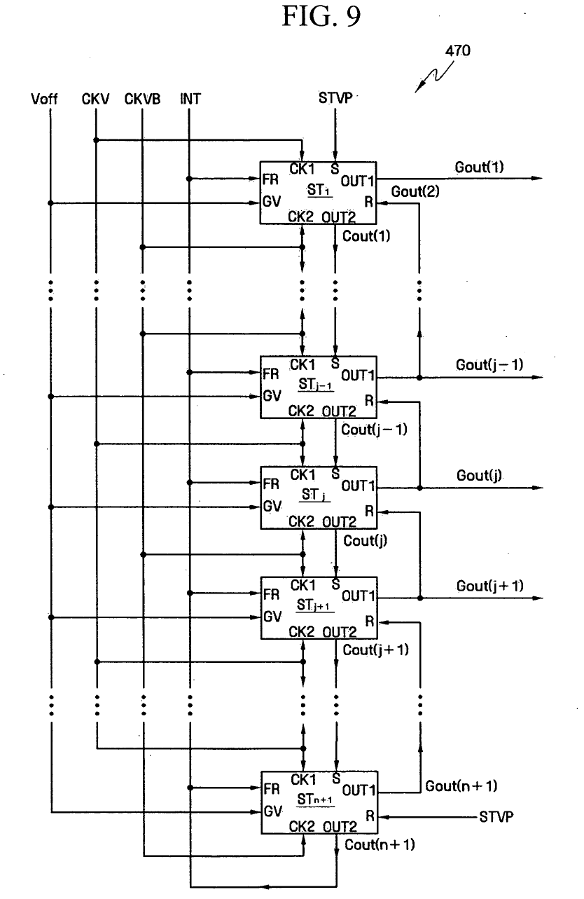

When the gate driver 470 is enabled by the scan-start signal STVP, the gate driver 470 receives a clock signal CKV, a clock-bar signal CKVB, and a gate-off voltage Voff and provides gate driving signals to the plurality of gate lines G1-Gn. The gate driver 470 will be described later in more detail with reference to FIGS. 9 to 11.

The data driver 700 receives an image signal DAT and a data control signal CONT from the timing controller 500, and supplies an image data voltage corresponding to the image signal DAT to each of the data lines D1 to Dm. The data control signal CONT controls the operation of the data driver 700, and includes, for example, a horizontal start signal (not shown) for starting an operation of the data driver 700 and a load signal (not shown) for instructing an output of two data voltages, but is not limited thereto. The data driver 700 is an integrated circuit (“IC”), and is connected to the liquid crystal panel 300 in a tape carrier package (“TCP”) manner; however, the present invention is not limited thereto. In exemplary embodiments, the data driver 700 may be formed on the non-display area PA of the liquid crystal panel 300 and may include thin film transistors.

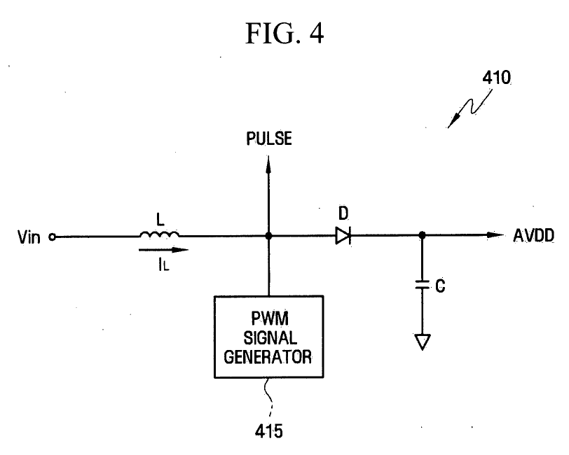

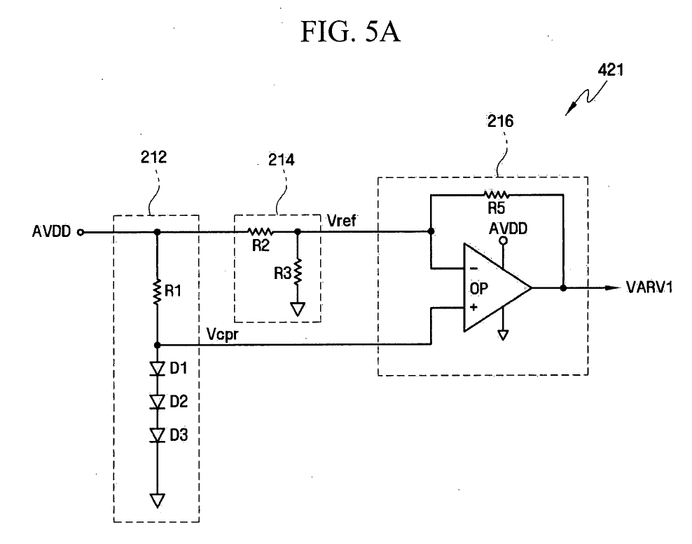

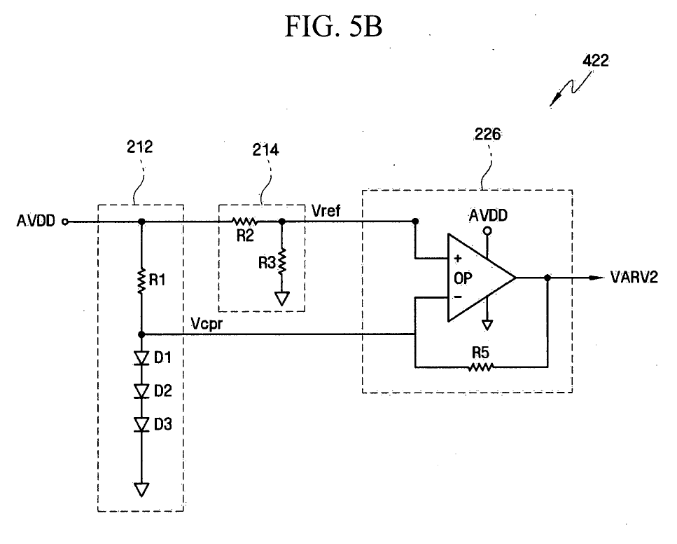

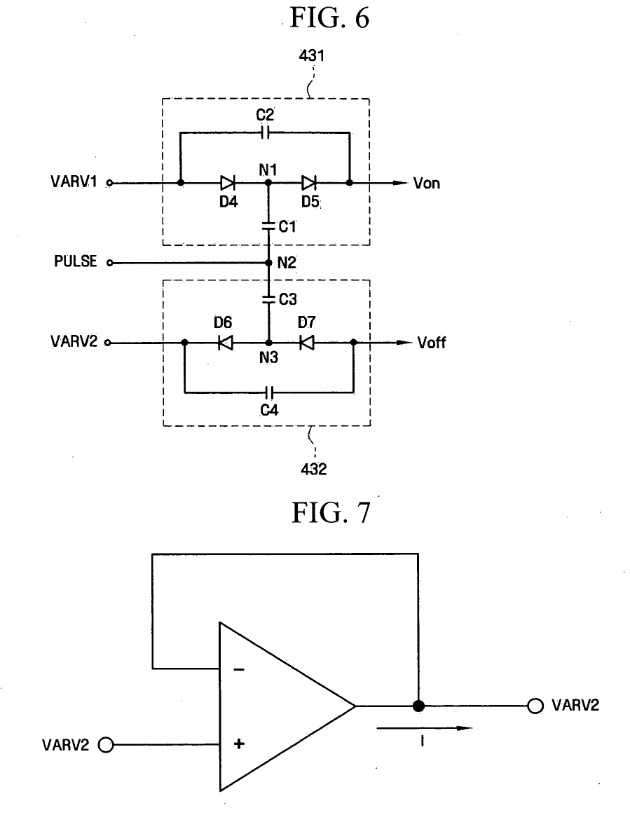

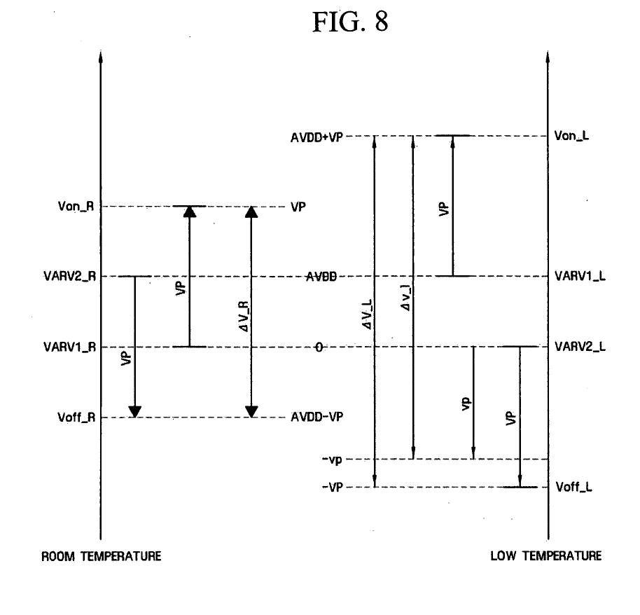

The gate-voltage generator 450 will be described now in more detail with reference to FIGS. 3 to 8. FIG. 3 is a block diagram of a gate-voltage generator shown in FIG. 1. FIG. 4 is a circuit diagram of a boost converter shown in FIG. 3. FIG. 5A and FIG. 5B are circuit diagrams illustrating respectively the first temperature-compensation unit 421 and the second temperature-compensation unit 422 shown in FIG. 3 according to an exemplary embodiment of the present invention. FIG. 6 is a circuit diagram illustrating a first charge-pumping unit and a second charge-pumping unit shown in FIG. 3. FIG. 7 is a circuit diagram illustrating a voltage follower shown in FIG. 3, and FIG. 8 is a diagram illustrating a voltage margin between Von and Voff at room temperature and at a low temperature.

Referring to FIG. 3, the gate-voltage generator 450 includes a boost converter 410, a gate-on voltage generator 441, and a gate-off voltage generator 442. The gate-off voltage generator 442 may hereinafter be referred to as a gate-off voltage generating circuit 422.

The boost converter 410 receives and boosts the first input voltage Vin and generates a driving voltage AVDD and a pulse signal PULSE. The boost converter 410 may be a DC-DC converter or another kind of converter.

Further, referring to FIG. 4, the boost converter 410 includes an inductor L to which the first input voltage Vin is applied, a diode D, the anode terminal of which is connected to the inductor L and the cathode terminal of which is connected to the output terminal at which the driving voltage AVDD appears, a capacitor C connected between the cathode of the diode D and a ground terminal, and a pulse width modulation (PWM) signal generator 415 connected to the anode terminal of the diode D.

The PWM signal generator 415 receives an input signal (not shown) outputs a pulse signal, the width of which is controlled according to the voltage level of the input signal. For example, the PWM signal generator 415 may comprise a comparator (not shown). The comparator compares the input signal with a reference signal and outputs a high level when the voltage level of the input signal is larger than that of the reference signal, and outputs a low level when the voltage level of the input signal is smaller than that of the reference signal. Thus, PWM signal generator 415 outputs the pulse signal, the duty ratio of which is controlled according to the voltage level of the input signal.

In the operation of the boost converter 410, when the pulse signal PULSE output of the PWM signal generator 415 is at a low level, the current IL flowing to the inductor L, in response to the first input voltage Vin applied to the inductor L, increases slowly according to the current and voltage characteristics of the inductor L.

When the pulse signal PULSE output of the PWM signal generator 415 changes to a high level, the current IL flow to the diode D and the capacitor C may be charged according to the current and voltage characteristics of the capacitor C. Accordingly, the first input voltage Vin is boosted to a predetermined voltage level to then be output as the driving voltage AVDD.

The gate-on voltage generator 441 comprises a first temperature-compensation unit 421 and a first charge-pumping unit 431. The gate-on voltage generator 441 receives the driving voltage AVDD and the pulse signal PULSE from the boost converter 410 and outputs the gate-on voltage Von.

The first temperature-compensation unit 421 outputs a first temperature-dependent variable voltage VARV1, the voltage level of which increases when the ambient temperature falls, and decreases when the ambient temperature rises. The first temperature-compensation unit 421 will be described later in more detail with reference to FIG. 5A.

The first charge-pumping unit 431 receives the first temperature-dependent variable voltage VARV1 and the pulse signal PULSE, and shifts the first temperature-dependent variable voltage VARV1 by the amplitude of the pulse signal PULSE, and outputs the gate-on voltage Von. The first charge-pumping unit 431 will be described later in more detail with reference to FIG. 6.

Therefore, the gate-on voltage generator 441 outputs the gate-on voltage Von, the voltage level of which increases when the ambient temperature falls, and decreases when the ambient temperature rises.

The gate-off voltage generator 442 comprises a second temperature-compensation unit 422, a second charge-pumping unit 432 and a voltage follower 425. The gate-off voltage generator 442 receives the driving voltage AVDD and the pulse signal PULSE from the boost converter 410 and outputs the gate-off voltage Voff.

The second temperature-compensation unit 422 outputs a second temperature-dependent variable voltage VARV2, the voltage level of which increases when the ambient temperature rises, and decreases when the ambient temperature falls. The second temperature-compensation unit 422 will be described later in more detail with reference to FIG. 5B.

The second charge-pumping unit 432 receives the second temperature-dependent variable voltage VARV2 and the pulse signal PULSE, and shifts the second temperature-dependent variable voltage VARV2 by the amplitude of the pulse signal PULSE and outputs the gate-off voltage Voff. The second charge-pumping unit 432 will be described later in more detail with reference to FIG. 6.

The voltage follower 425 receives the second temperature-dependent variable voltage VARV2 from the second temperature-compensation unit 422, and transfers the second temperature-dependent variable voltage VARV2 to the second charge-pumping unit 432. The voltage follower 425 provides sufficient current to the second charge-pumping unit 432 so that the second charge-pumping unit 432 shifts the second temperature-dependent variable voltage VARV2 by the amplitude of the pulse signal PULSE. The voltage follower 425 will be described later in more detail with reference to FIG. 7.

Therefore, the gate-off voltage generator 442 outputs the gate-off voltage Voff, the voltage level of which increases when the ambient temperature rises, and decreases when the ambient temperature falls.

The first and second temperature-compensation units, the first and second charge-pumping units, and the voltage follower will now be described in more detail.

First, referring to FIG. 5A, the first temperature-compensation unit 421 includes a comparison voltage generator 212 outputting a comparison voltage Vcpr, the level of which varies according to the ambient temperature, more specifically the comparison voltage Vcpr varies substantially inversely with the ambient temperature, a reference voltage generator 214 dividing the driving voltage AVDD and generating a reference voltage Vref, and a first amplifier 216 amplifying a difference between the comparison voltage Vcpr and the reference voltage Vref and outputting the first temperature-dependent variable voltage VARV1.

The comparison voltage generator 212 comprises one or more diodes D1, D2, D3 having a threshold voltage or voltage drop across each diode which is substantially inversely proportional to the ambient temperature. As shown in FIG. 5A, a resistor R1 is connected in series with diodes D1, D2, and D3 between the AVDD supply and ground. The comparison voltage Vcpr is the voltage at the connection between the resistor R1 and diode D1. For example, assuming that the driving voltage AVDD is approximately 12V and the threshold voltage of each of the diodes D1, D2, and D3 is approximately 0.57V at room temperature, the comparison voltage Vcpr is approximately 1.7V or (3×0.57V) at room temperature. When the ambient temperature falls below room temperature, the voltage level of the comparison voltage Vcpr rises and may increase to approximately 2V, with the increase in Vcpr being due to an increase of the threshold voltage of each diode.

The reference voltage generator 214 may be a voltage divider. That is to say, the reference voltage generator 214 generates the reference voltage Vref derived from the driving voltage AVDD divided by a plurality of resistors R2 and R3 connected in series. The level of the reference voltage Vref is maintained at a fixed value regardless of a change of the ambient temperature, the reference voltage Vref, however, may be an intermediate value over a variation range of the reference voltage Vref varying very slightly according to the ambient temperature and still be a relatively fixed voltage. For example, assuming that the level of the comparison voltage Vcpr varies between approximately 1.7V and 2V, the level of the reference voltage Vref may be substantially fixed at 1.8V.

The first amplifier 216 comprises an operational amplifier OP. The first amplifier 216 compares the comparison voltage Vcpr with the reference voltage Vref and outputs first temperature-dependent variable voltage VARV1 according to the comparison result. In this exemplary embodiment, the first amplifier 216 operates as a comparator.

Assume that at room temperature the level of the comparison voltage Vcpr is 1.7V, and the level of the reference voltage Vref is 1.8V, then the operational amplifier OP outputs a value of VARV1 of 0V, because the level of the comparison voltage Vcpr is smaller than the level of the reference voltage Vref. Assuming, on the other hand, that the level of the comparison voltage Vcpr is 2V at a low temperature and the level of the reference voltage is 1.8V, then the operational amplifier OP outputs the driving voltage AVDD, because the level of the comparison voltage Vcpr is larger than the level of the reference voltage Vref.

That is, the first amplifier 216 outputs 0V when the level of the comparison voltage Vcpr smaller than the level of the reference voltage Vref, while the first amplifier 216 outputs the driving voltage AVDD when the level of the comparison voltage Vcpr larger than the level of the reference voltage Vref. Therefore, the first temperature-dependent variable voltage VARV1 may be 0V at room temperature, while the first temperature-dependent variable voltage VARV1 may be the driving voltage AVDD at the low temperature.

The first amplifier 216 may also include a feedback-resister R5. The feedback-resister R5 is connected between an inversion terminal (−) of the operational amplifier OP and an output terminal of the operational amplifier OP to form a negative-feedback closed loop. If the first temperature-dependent variable voltage VARV1 varies rapidly from 0V to the driving voltage AVDD, or from the driving voltage AVDD to 0V, the liquid crystal display may fail. The feedback-resister R5 prevents rapid variation of the first temperature-dependent variable voltage VARV1.

Referring to FIG. 5B, the second temperature-compensation unit 422 includes a comparison voltage generator 212 outputting a comparison voltage Vcpr, the level of which varies according to the ambient temperature, more specifically Vcpr varies inversely with the ambient temperature, a reference voltage generator 214 dividing the driving voltage AVDD and generating a reference voltage Vref, and a second amplifier 226 amplifying the difference between the comparison voltage Vcpr and the reference voltage Vref, and outputting the second temperature-dependent variable voltage VARV2. For explanatory convenience, components each having the same function in the exemplary embodiment shown in FIG. 5B and in FIG. 5A are respectively identified by the same reference numerals, and further detailed description thereof will be omitted.

The second amplifier 226 comprises an operational amplifier OP. The second amplifier 226 compares the comparison voltage Vcpr with the reference voltage Vref, and outputs the second temperature-dependent variable voltage VARV2 according to the comparison result. The comparison voltage Vcpr is applied to the negative input terminal of the operational amplifier OP and the reference voltage Vref is applied to the positive input terminal of the operational amplifier OP. Here, the second amplifier 226 operates as a comparator.

For example, assume the level of the comparison voltage Vcpr is 1.7V at room temperature and the level of the reference voltage is 1.8V, the operational amplifier OP outputs the driving voltage AVDD, because the level of the comparison voltage Vcpr is smaller than the level of the reference voltage Vref. For example, assume the level of the comparison voltage Vcpr is 2V at a low temperature and the level of the reference voltage is 1.8V, the operational amplifier OP outputs 0V, because the level of the comparison voltage Vcpr is larger than the level of the reference voltage Vref.

That is, the second amplifier 226 outputs the driving voltage AVDD when the level of the comparison voltage Vcpr smaller than the level of the reference voltage Vref, while the second amplifier 226 outputs 0V when the level of the comparison voltage Vcpr is larger than the level of the reference voltage Vref. Therefore, the second temperature-dependent variable voltage VARV2 may be the driving voltage AVDD at room temperature, while the second temperature-dependent variable voltage VARV2 may be 0V at the low temperature.

Next, the first and second charge-pumping units will now be described in more detail with reference to FIG. 6.

The first charge-pumping unit 431 includes fourth and fifth diodes D4 and D5 and first and second capacitors C1 and C2. The first temperature-dependent variable voltage VARV1 is supplied to the anode terminal of the fourth diode D4, the cathode terminal of which is connected to a first node N1. The first capacitor C1 is connected between the first node N1 and a second node N2 to which the pulse signal PULSE is applied. The anode terminal of the fifth diode D5 is connected to the first node N1, and a gate-on voltage Von is output at the cathode terminal of the fifth diode D5. The second capacitor C2 is connected between the anode terminal of the fourth diode D4 and the cathode terminal of the fifth diode D5.

In the operation of the first charge-pumping unit 431, when the pulse signal PULSE is applied to the first capacitor C1, the first node N1 outputs a pulse of a high voltage level increased by the voltage level of the pulse signal PULSE. The fifth diode D5 and the second capacitor C2 clamp the voltage of the first node N1 to then output the gate-on voltage Von. That is, the gate-on voltage Von is a DC voltage shifted from the first temperature-dependent variable voltage VARV1 by approximately the voltage level of the pulse signal PULSE.

The second charge-pumping unit 432 includes sixth and seventh diodes D6 and D7 and third and fourth capacitors C3 and C4. The second temperature-dependent variable voltage VARV2 is applied to the cathode terminal of the sixth diode D6, the anode terminal of which is connected to a third node N3. The third capacitor C3 is connected between the third node N3 and the second node N2 to which the pulse signal PULSE is applied. The cathode terminal of the seventh diode D7 is connected to the third node N3 and the anode terminal of the seventh diode D7 output a gate-off voltage Voff. The fourth capacitor C4 is connected between the cathode terminal of the sixth diode D6 and the anode terminal of the seventh diode D7.

In the operation of the second charge-pumping unit 432, when the pulse signal PULSE is applied to the third capacitor C3, the third node N3 outputs a pulse of a low voltage level decreased by the voltage level of the pulse signal PULSE. The sixth diode D6 and the fourth capacitor C4 clamp the voltage of the third node N3 to then output a gate-off voltage Voff. That is, the gate-off voltage Voff is a DC voltage shifted from the second temperature-dependent variable voltage VARV2 by approximately the voltage level of the pulse signal PULSE.

While, in the exemplary embodiment as shown in FIG. 6, the first and second charge-pumping units 431 and 432 each include two diodes and two capacitors by way of example, the invention is not limited to the illustrated example and the charge-pumping units 431 and 432 may be configured with a combination of three or more diodes and three or more capacitors. For example, if the first and second charge-pumping units 431 and 432 each include four diodes and four capacitors, the first and second charge-pumping units 431 and 432 shift the first and second temperature-dependent variable voltage VARV1 and VARV2 by double the voltage level of the pulse signal PULSE, respectively. Generally, if the first and second charge-pumping units 431 and 432 include 2m diodes and 2m capacitors (m is an integer), the first and second charge-pumping units 431 and 432 shift the first and second temperature-dependent variable voltages VARV1 and VARV2 by m voltage levels of the pulse signal PULSE, respectively.

The voltage follower will now be described in more detail with reference to FIG. 7.

The first and second charge-pumping units 431 and 432 may not be able to shift the first and second temperature-dependent variable voltages VARV1 and VARV2 by the voltage level of the pulse signal PULSE as required to drive the liquid crystal display.

For example, if the liquid crystal panel 300 includes a heavy load, the current consumption of the liquid crystal panel 300 is big. The bigger the capacitance of the common electrode PE is, the bigger the current consumption of the liquid crystal panel 300 is. If the current consumption of the liquid crystal panel 300 is big, the current supplied to the second charge-pumping unit 432 may not be sufficient for the second charge-pumping unit 432 to shift the second temperature-dependent variable voltage VARV2 by the voltage level of the pulse signal PULSE.

However, the voltage follower 425 of the present invention provides sufficient current to the second charge-pumping unit 432 so that the second charge-pumping unit 432 can shift the second temperature-dependent variable voltage VARV2 by the voltage level of the pulse signal PULSE.

The voltage margin at a low temperature will now be described in more detail with reference to FIG. 8. Here, the voltage margin at a low temperature means the difference between the gate-on voltage and the gate-off voltage for driving the LCD at a low temperature. The voltage margin at room temperature is discussed first and then the voltage margin at a low temperature is discussed.

Referring to FIG. 8, at room temperature, the first temperature-dependent variable voltage VARV1_R which the first temperature-compensation unit 421 outputs is 0V, and the second temperature-dependent variable voltage VARV2_R which the second temperature-compensation unit 422 outputs is the driving voltage AVDD. The first charge-pumping unit 431 shifts the first temperature-dependent variable voltage VARV1_R by the voltage level VP of the pulse signal PULSE. Then, the gate-on voltage Von_R is VP at room temperature. The second charge-pumping unit 432 shifts the second temperature-dependent variable voltage VARV2_R by the voltage level VP of the pulse signal PULSE so that the gate-off voltage Voff_R is (AVDD−VP). Therefore, the voltage margin ΔV_R at room temperature is (−AVDD+2VP).

At a low temperature, the first temperature-dependent variable voltage VARV1_L which the first temperature-compensation unit 421 outputs is the driving voltage AVDD, and the second temperature-dependent variable voltage VARV2_L which the second temperature-compensation unit 422 outputs is 0V. The first charge-pumping unit 431 shifts the first temperature-dependent variable voltage VARV1_L by the voltage level VP of the pulse signal PULSE so that the gate-on voltage Von_L is (AVDD+VP) at a low temperature.

The second charge pumping unit 432 shifts the second temperature-dependent variable voltage VARV2_L by the voltage level VP of the pulse signal PULSE. Then, the gate-off voltage Voff₋L is (0V−VP). Therefore, the voltage margin ΔV_L at low temperature is (AVDD+2VP).

If the current supplied to the second charge-pumping unit 432 is not sufficient, the second charge-pumping unit 432 may shift the second temperature-dependent variable voltage VARV2_L by the voltage level vp, which is smaller than the voltage level of the pulse signal PULSE VP. Therefore, the voltage margin ΔV_L at a low temperature may be Δv_1.

However, the second charge-pumping unit 432 shifts the second temperature-dependent variable voltage VARV2_L by the voltage level VP of the pulse signal PULSE because the voltage follower 425 provides sufficient current to the second charge-pumping unit 432. Therefore, the voltage margin ΔV_L at a low temperature is (AVDD+2VP).

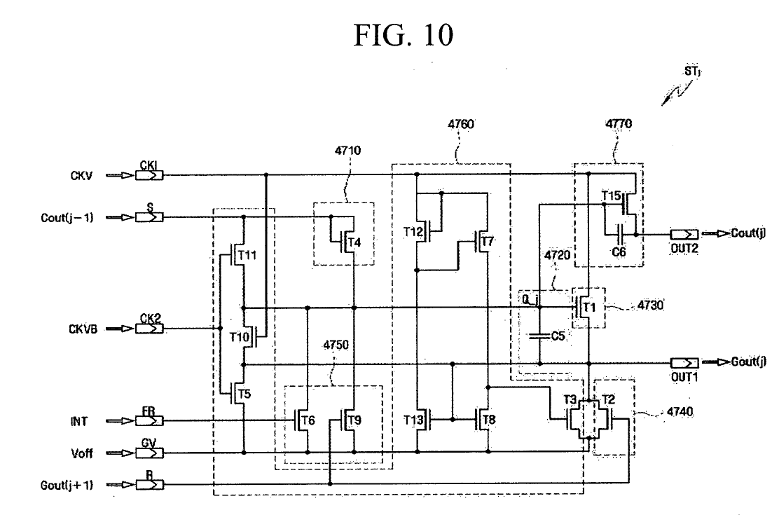

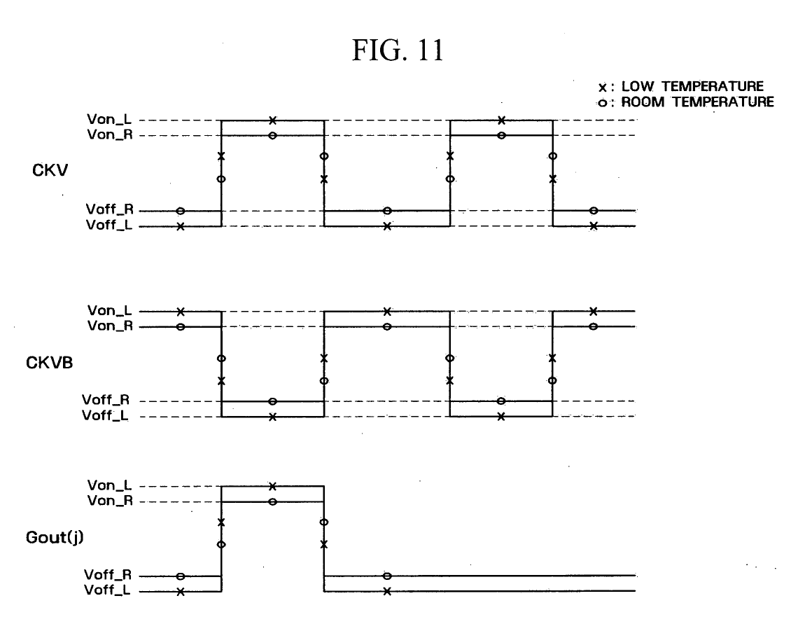

The gate driver will now be described in more detail with reference to FIGS. 9 to 11. FIG. 9 is an exemplary block diagram illustrating a gate driver, FIG. 10 is an exemplary circuit diagram of the j-th stage shown in FIG. 9, and FIG. 11 is a signal diagram illustrating a clock signal input to a gate driver, a clock bar signal input to the gate driver, and a gate signal output from the gate driver.

The gate driver 470, which is enabled by the first scan start signal STVP, sequentially supplies a gate signal of the plurality of gate signals to each gate line G₁ to Gₙ, respectively. The gate driver 470 is now described in more detail with reference to FIG. 9.

The gate driver 470 includes a plurality of stages ST₁ to STₙ₊₁, which are connected to one another in a cascade manner, as illustrated in FIG. 9. Each of the stages ST₁ to STₙ, except for the final stage STₙ₊₁, is connected to a respective corresponding gate line of the plurality of gate lines G₁ to Gₙ, and the stages ST₁ to STₙ output gate signals Gout(1) to Gout(n), respectively. Each of the stages ST₁ to STₙ₊₁ receives the gate-off voltage Voff, the clock signal CKV, the clock bar signal CKVB and an initializing signal INT. In the current exemplary embodiment, the initializing signal INT may be supplied by the clock generator 460. However, the present invention is not limited thereto.

In exemplary embodiments, each of the stages ST₁ to STₙ₊₁ may include a first clock terminal CK1, a second clock terminal CK2, a set terminal S, a reset terminal R, a power-supply-voltage terminal GV, a frame-reset-terminal FR, a gate-output terminal OUT1 and a carry output terminal OUT2.

Specifically, and for purposes of further illustration, among the stages ST₁ to STₙ₊₁, the j-th stage STⱼ, for example, includes a set terminal S to which a carry signal Cout(j−1) of a previous stage STⱼ₋₁ is input, a reset terminal R to which a gate signal Gout(j+1) of a next stage STⱼ₊₁ is input, a first clock terminal CK1 and a second clock terminal CK2 to which the clock signal CKV and the clock bar signal CKVB are input, respectively, the power-supply voltage terminal GV to which the gate-off voltage Voff is input and the frame-reset-terminal FR to which the initializing signal INT or the carry signal Cout(n+1) of a last stage STₙ₊₁ is input. The j-th stage STⱼ includes a gate-output terminal OUT1 through which a gate signal Gout(j) is output, and a carry output terminal OUT2 through which the carry signal Cout(j) is output.

However, the first scan-start signal STVP is input to the set terminal S of the first stage ST₁ instead of the carry signal of a previous stage, and the first scan-start signal STVP is input to the reset terminal R of the final stage STₙ₊₁ instead of a gate signal of a next stage.

The j-th stage STⱼ is described hereinafter in further detail with reference to FIG. 10.

Referring now to FIG. 10, the j-th stage STⱼ includes a buffer unit 4710, a charge unit 4720, a pull-up unit 4730, a carry signal generator 4770, a pull-down unit 4740, a discharge unit 4750 and a holding unit 4760. The j-th stage STⱼ receives the carry signal Cout(j−1) of the previous stage STⱼ₋₁, the clock signal CKV and the clock bar signal CKVB.

The buffer unit 4710 includes a diode-connected transistor T4. The buffer unit 4710 supplies the carry signal Cout(j−1) of the previous stage STⱼ₋₁ to the charge unit 4720, the carry signal generator 4770 and the pull-up unit 4730. The carry signal Cout(j−1) of the previous stage STⱼ₋₁ is input through the set terminal S of the j-th stage STⱼ.

The charge unit 4720 includes a capacitor C5 having a first terminal connected to a source terminal of the transistor T4, the pull-up unit 4730 and the discharge unit 4750, and the capacitor C5 having a second terminal connected to the gate-output terminal OUT1.

The pull-up unit 4730 includes a transistor T1 having a drain terminal connected to the first clock terminal CK1, a gate terminal connected to the charge unit 4720 and a source terminal connected to the gate-output terminal OUT1.

The carry signal generator 4770 includes a transistor T15 having a drain terminal connected to the first clock terminal CK1, a source terminal connected to the carry output terminal OUT2 and a gate terminal connected to the buffer unit 4710. The carry signal generator 4770 includes a capacitor C6 having a first terminal connected to the gate terminal of the transistor T15 and a second terminal connected to the source terminal of the transistor T15.

The pull-down unit 4740 includes transistor T2 having a drain terminal connected to the source terminal of the transistor T1 and to the second terminal of the capacitor C5, a source terminal connected to the power supply voltage terminal GV and a gate terminal connected to the reset terminal R.

The discharge unit 4750 includes a transistor T9 which discharges the charge unit 4720 in response to the gate signal Gout(j+1) of the next stage STⱼ₊₁ and a transistor T6 which discharges the charge unit 4720 in response to the initializing signal INT. The transistor T9 includes a gate terminal connected to the reset terminal R, a drain terminal connected to the first terminal of the capacitor C6 and a source terminal connected to the power supply voltage terminal GV.

When the gate signal Gout(j) transitions to the high level (e.g., the second level) from the low level (e.g., the first level), the holding unit 4760, which includes a plurality of transistors T3, T5, T7, T8, T10, T11, T12 and T13, holds the gate signal Gout(j) at the high level. When the gate signal Gout(j) transitions to the low level from the high level, the holding unit 4760 holds the gate signal Gout(j) at the low level during one frame regardless of the voltage level of the clock signal CKV and clock bar signal CKVB.

The input and output signals of the gate driver 470 are described hereinafter in further detail with reference to FIG. 11.

As described above, because the amplitudes of the clock signal CKV and the clock bar signal CKVB vary according to the ambient temperature, the amplitude swing between Von_L and Voff_L of the signals CKV and CKVB at low temperature is larger than the amplitude swing between Von_R and Voff_R of the signals CKV and CKVB at room temperature. Likewise, the amplitude swing between Von_L and Voff_L of the gate signal Gout(j) at low temperature is larger than the amplitude swing between Von_R and Voff_R of the gate signal Gout(j) at room temperature.

Therefore, the voltage margin is increased at low temperature and the current driving capacity of a gate driver 470 does not decrease. Also the display quality of the LCD can be enhanced.

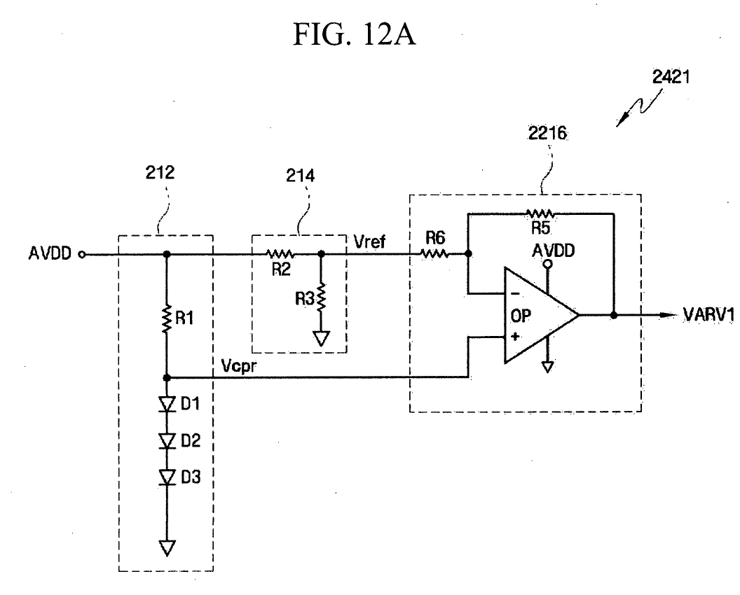

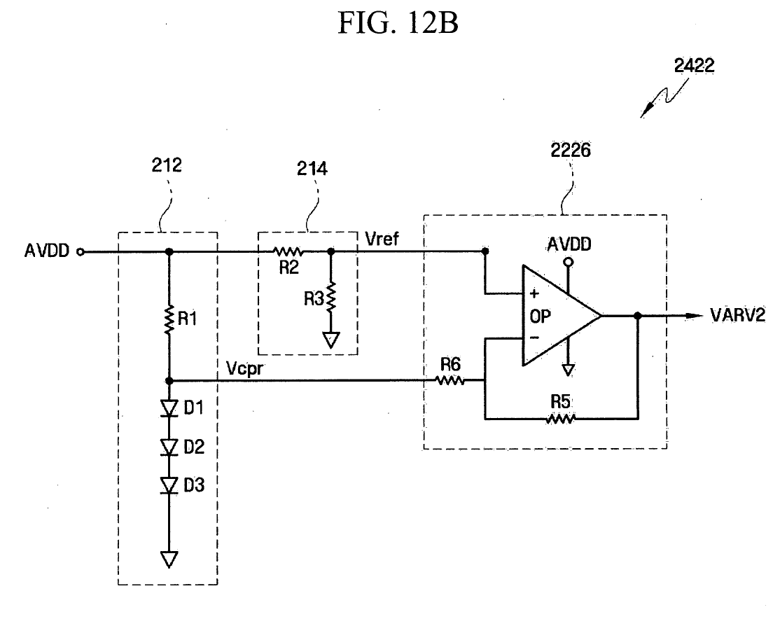

An exemplary embodiment according to the present invention will now be described with reference to FIGS. 12A and 12B. FIG. 12A and FIG. 12B are circuit diagrams illustrating, respectively, a first temperature-compensation unit and a second temperature-compensation unit shown in FIG. 3 according to an exemplary embodiment of the present invention. For explanatory convenience, components each having the same function as described in the exemplary embodiment shown in FIGS. 5A and 5B are respectively identified by the same reference numerals, and a detailed description thereof will be omitted.

Referring to the 12A, the first temperature-compensation unit 2421 comprises a comparison voltage generator 212, a reference voltage generator 214, and a first amplifier 2216 amplifying a difference between the comparison voltage Vcpr and the reference voltage Vref and outputting the first temperature-dependent variable voltage VARV1.

The first amplifier 2216 includes an operational amplifier OP and resistors R5 and R6. The first amplifier 2216 amplifies a difference between the comparison voltage Vcpr and the reference voltage Vref, and outputs the first temperature-dependent variable voltage VARV1.

The first amplifier 2216 increases a change of the temperature-dependent variable voltage VARV1 according to the change of the ambient temperature.

For example, when the ambient temperature falls, the voltage level of the comparison voltage Vcpr increases from 1.7V to 2V. Then, the first temperature-dependent variable voltage VARV1 increases from 0V to AVDD which may be 12V for example. The change of the first temperature-dependent variable voltage VARV1 is controlled by the voltage gain of the first amplifier 2216. Here, the voltage gain of the first amplifier 2216 is controlled by the resistance values of the resistors R5 and R6.

Referring to FIG. 12B, the second temperature-compensation unit 2422 includes a comparison voltage generator 212, a reference voltage generator 214, and a second amplifier 2226 amplifying the difference between the comparison voltage Vcpr and the reference voltage Vref and outputting the second temperature-dependent variable voltage VARV2.

The second amplifier 2226 increases a change of the second temperature-dependent variable voltage VARV2 according to the change of the ambient temperature.

For example, when the ambient temperature falls, the voltage level of the comparison voltage Vcpr increases from 1.7V to 2V. Then, the second temperature-dependent variable voltage VARV2 decreases from 12V to 0V. The change of the temperature-dependent variable voltage VARV1 is controlled by resistors R5 and R6 which determine a voltage gain of the second amplifier 2226. The change of the second temperature-dependent variable voltage VARV2 is controlled by resistors R5 and R6 which determine a voltage gain of the second amplifier 2226.

In summary, the change of the first and second temperature-dependent variable voltages VARV1 and VARV2 are controlled by the voltage gains of the first and second amplifiers 2216 and 2226. The voltage gains of the first and second amplifier 2216 and 2226 are controlled by the resistance values of the resistors R5 and R6. That is, the voltage levels of the gate-on voltage Von and gate-off voltage Voff are controlled by resistors R5 and R6.

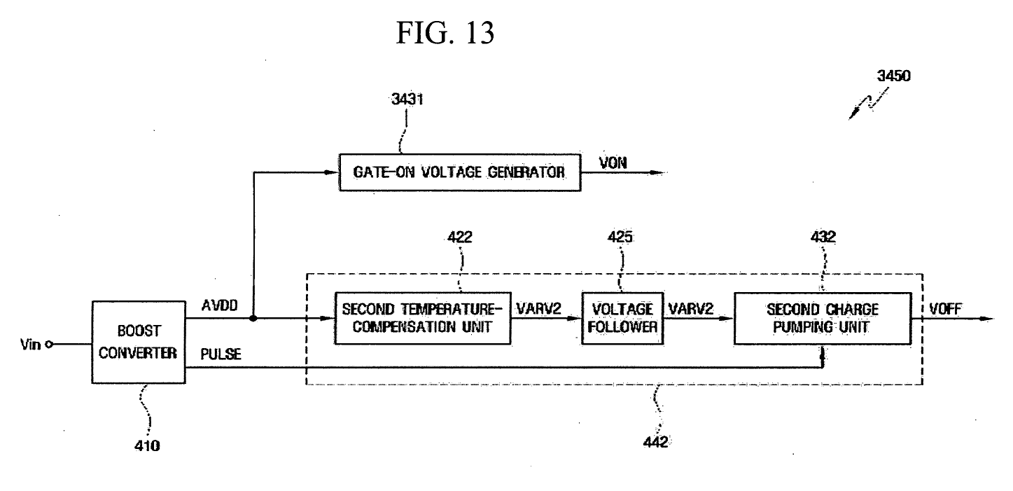

An exemplary embodiment according to the present invention will now be described with reference to FIG. 13. FIG. 13 is a block diagram illustrating a gate-voltage generator according to an exemplary embodiment of the present invention.

The gate-voltage generator shown in FIG. 13 includes a boost converter 410, a gate-on voltage generator 3431 and a gate-off voltage generator 442.

The gate-on voltage generator 3431 of the gate-voltage generator 3450 receives the driving voltage AVDD, and-outputs the gate-on voltage Von, and does not change the voltage level of the gate-on voltage Von according to the ambient temperature.

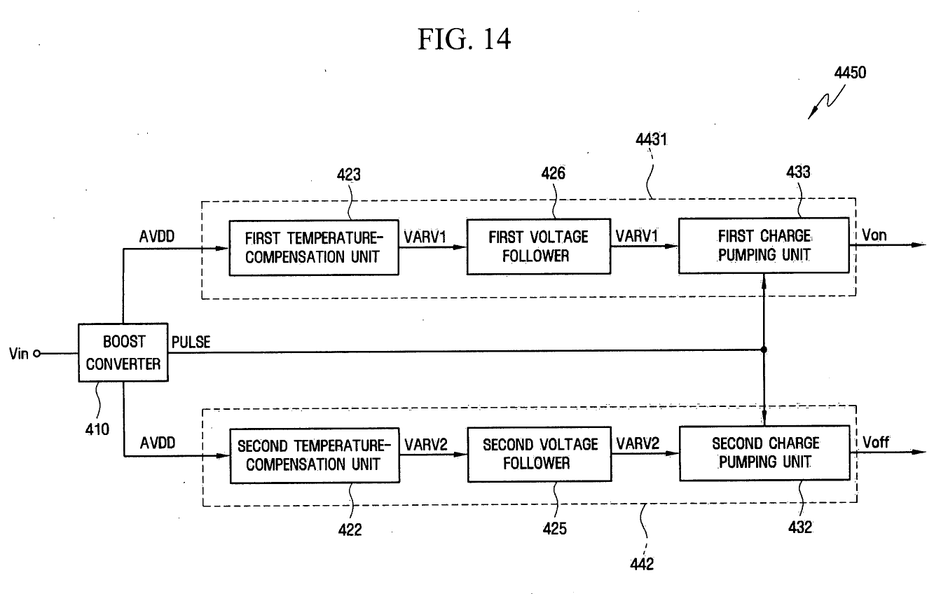

An exemplary embodiment according to the present invention will now be described with reference to FIG. 14. FIG. 14 is a block diagram illustrating a gate-voltage generator according to an exemplary embodiment of the present invention.

The gate-on voltage generator 4431 of the gate-voltage generator 4450 includes a first voltage follower 426 connected between the first temperature-compensation unit 423 and the first charge-pumping unit 433. The gate-off voltage generator 442 of the gate-voltage generator 4450 includes the second voltage follower 425 connected between the second temperature-compensation unit 422 and the second charge-pumping unit 432.

The first voltage follower 426 provides sufficient current to the first charge-pumping unit 433 so that the first charge-pumping unit 433 shifts the first temperature-dependent variable voltage VARV1 by the amplitude of a pulse signal PULSE.

As described above, the gate-off voltage generator according to exemplary embodiments of the present invention, the driving device, and the LCD including the same, provide at least the following advantages.

First, the current-driving capacity of a gate driver is not decreased when the ambient temperature is lowered.

Second, since the current-driving capacity of a gate driver is not decreased even at a lower ambient temperature, the display quality of the display apparatus can be enhanced.

In conclusion, those skilled in the art will appreciate that many variations and modifications can be made to the exemplary embodiments without substantially departing from the principles of the present invention. Therefore, the disclosed exemplary embodiments of the invention are used in a generic and descriptive sense only and not for purposes of limitation.

What is claimed is:

1. A driving device comprising:
a boost converter to receive and boost a first input voltage and output a driving voltage and a pulse signal;
a gate-on voltage generator to receive the driving voltage and output a gate-on voltage; and
a gate-off voltage generator including a first temperature-compensation unit to receive the driving voltage and output a first temperature-dependent variable voltage, the level of which varies according to an ambient temperature, a first voltage follower to receive and provide at an output the first temperature-dependent variable voltage, and a first charge-pumping unit coupled to the output of the first voltage follower, the first charge-pumping unit being operative to shift the first temperature-dependent variable voltage as a function of an amplitude of the pulse signal and output a gate-off voltage.

2. The driving device of claim 1, wherein the gate-on voltage generator comprises a second temperature-compensation unit to receive the driving voltage and output a second temperature-dependent variable voltage, the level of which varies as a function of the ambient temperature, and a second charge-pumping unit to shift the second temperature-dependent variable voltage as a function of the amplitude of the pulse signal and output the gate-on voltage.

3. The driving device of claim 2, wherein the gate-on voltage generator further comprises a second voltage follower to receive and transfer the second temperature-dependent variable voltage to the second charge-pumping unit.

4. The driving device of claim 1, further comprising a clock generator unit configured for receiving the gate-on voltage from the gate-on voltage generator, receiving the gate-off voltage from the gate-off voltage generator and generating a clock signal having a swing of a voltage difference between the gate-on voltage and the gate-off voltage.

5. The driving device of claim 4, wherein the amplitude of the clock signal increases when the ambient temperature falls, and the amplitude of the clock signal decreases when the ambient temperature rises.

6. The driving device of claim 1, wherein the first temperature-compensation unit comprises a comparison voltage generator including one or more diodes having a threshold voltage, which is substantially inversely proportional to a change of the ambient temperature, receiving the driving voltage and generating a comparison voltage, the level of which varies according to the ambient temperature, a reference voltage generator dividing the driving voltage and generating a reference voltage, and an operational amplifier amplifying a difference between the comparison voltage and the reference voltage.

7. A gate-off voltage generating circuit comprising:
a voltage follower to receive and transfer a temperature-dependent variable voltage; and
a charge-pumping unit to shift the transferred temperature-dependent variable voltage as a function of the amplitude of a pulse signal and output a gate-off voltage.

8. The gate-off voltage generating circuit of claim 7, further comprising a temperature-compensation unit to receive a driving voltage and output the temperature-dependent variable voltage, the level of which varies according to an ambient temperature, to the voltage follower.

9. The gate-off voltage generating circuit of claim 8, wherein the voltage follower comprises an operational amplifier.

10. The gate-off voltage generating circuit of claim 8, wherein the voltage follower provides sufficient current to the charge-pumping unit so that the charge-pumping unit shifts the transferred temperature-dependent variable voltage by the amplitude of a pulse signal.

11. The gate-off voltage generating circuit of claim 8, wherein the amplitude of the temperature-dependent variable voltage increases when the ambient temperature falls, and the amplitude of the temperature-dependent variable voltage decreases when the ambient temperature rises.

12. The gate-off voltage generating circuit of claim 8, wherein the temperature-compensation unit comprises one or more diodes having a threshold voltage that is substantially inversely proportional to a change of the ambient temperature.

13. The gate-off voltage generating circuit of claim 8, wherein the temperature-compensation unit further comprises an operational amplifier increases a change of the temperature-dependent variable voltage according to the change of the ambient temperature.

14. The gate-off voltage generating circuit of claim 8, wherein the temperature-compensation unit comprises a comparison voltage generator including one or more diodes having a threshold voltage which is substantially inversely proportional to a change of the ambient temperature, receiving the driving voltage and generating a comparison voltage, the level of which varies according to the ambient temperature, a reference voltage generator dividing the driving voltage and generating a reference voltage, and an operational amplifier amplifying a difference between the comparison voltage and the reference voltage.

15. A liquid crystal display (LCD) comprising:
a driving device including a boost converter to receive and boost a first input voltage and output a driving voltage and a pulse signal, a gate-on voltage generator to receive the driving voltage and output a gate-on voltage, a gate-off voltage generator including a first temperature-compensation unit to receive the driving voltage and output a first temperature-dependent variable voltage, the level of which varies according to the ambient temperature, a first voltage follower to receive and transfer the first temperature-dependent variable voltage, and a first charge-pumping unit to shift the transferred first temperature-dependent variable voltage by the amplitude of the pulse signal and output a gate-off voltage and a clock generator unit generating a clock signal having a swing of a voltage difference between the gate-on voltage and the gate-off voltage;
a gate driver to receive the clock signal and output a gate signal; and
a liquid crystal panel that includes a plurality of pixels to be turned on/off according to the gate signal, and that displays an image.

16. The LCD of claim 15, wherein the gate-on voltage generator comprises a second temperature-compensation unit to receive the driving voltage and output a second temperature-dependent variable voltage, the level of which varies according to the ambient temperature, and a second charge-pumping unit to shift the second temperature-dependent variable voltage by the amplitude of the pulse signal and output the gate-on voltage.

17. The LCD of claim 15, wherein the amplitude of the clock signal increases when the ambient temperature falls, and the amplitude of the clock signal decreases when the ambient temperature rises.

18. The LCD of claim 15, wherein the first temperature-compensation unit comprises a comparison voltage generator including one or more diodes having a threshold voltage, which is substantially inversely proportional to a change of the ambient temperature, receiving the driving voltage and generating a comparison voltage, the level of which varies according to the ambient temperature, a reference voltage generator dividing the driving voltage and generating a reference voltage, and an operational amplifier amplifying a difference between the comparison voltage and the reference voltage.

19. The LCD of claim 15, wherein the gate driver comprises a plurality of stages outputting the gate signal sequentially, each of the stages including at least one thin film transistor (TFT) made of amorphous silicon (a-Si).
